(19) United States
(12) Patent Application Publication
(10) Pub. No.: US 2024/0036469 A1
(43) Pub. Date: Feb. 1, 2024

(54) METHOD FOR MANUFACTURING THICKENED RESIST PATTERN, THICKENING SOLUTION, AND METHOD FOR MANUFACTURING PROCESSED SUBSTRATE

(71) Applicant: Merck Patent GmbH, Darmstadt (DE)

(72) Inventors: Tatsuro NAGAHARA, Kakegawa-shi (JP); Kazuma YAMAMOTO, Kakegawa-shi (JP)

(21) Appl. No.: 18/265,450

(22) PCT Filed: Dec. 14, 2021
(86) PCT No.: PCT/EP2021/085640

§ 371 Date: Jun. 6, 2023

(30) Foreign Application Priority Data
Dec. 17, 2020 (KR) 2020-209190

(51) Int. Cl. G03F 7/11; G03F 7/38; G03F 7/30; G03F 7/039; H01L 21/027

(52) U.S. Cl. CPC G03F 7/11; G03F 7/38; G03F 7/30; G03F 7/0397; H01L 21/0274

(57) ABSTRACT

[Problem] To provide a method for manufacturing a thickened resist pattern. [Means for Solution] A method for manufacturing a thickened resist pattern comprising the following steps: (1) applying a resist composition above a substrate to form a resist layer from the resist composition; (2a) exposing the resist layer; (2b) applying a thickening solution comprising a polymer (A) and a solvent (B) on the resist layer to form a thickening layer; and (3) developing the resist layer and the thickening layer.

### BACKGROUND OF THE INVENTION

### Technical Field

The present invention relates to a method for manufacturing a thickened resist pattern, a thickening solution used for the method, and a method for manufacturing a processed substrate.

### Background Art

In recent years, needs for high integration of LSI has been increasing, and making resist pattern finer is required. In order to respond such needs, lithography processes using KrF excimer laser (248 nm), ArF excimer laser (193 nm), extreme ultraviolet ray (EUV; 13 nm), X-ray of short wavelength, electron beam or the like have been put into practice.

In order to obtain a finer pattern, there is a method, in which a resist pattern formed in a range that can be stably obtained by a conventional method is covered with a composition comprising a polymer to thicken the resist pattern and the hole diameter or separation width made finer (for example, Patent Document 1). This mainly aims to thicken the width of the resist pattern, and it further applies the composition comprising a polymer after developing the resist pattern once.

Further, while a thicker resist pattern having a high aspect ratio is required, a composition using a vinyl resin and an amine compound has also been developed (Patent Document 2).

### PRIOR ART DOCUMENTS

### Patent Documents

[Patent document 1] JP 2014-170190 A
[Patent document 2] JP 2017-165846 A

### SUMMARY OF THE INVENTION

### Problems to be Solved by the Invention

The present inventors have considered that there are one or more problems still need improvements in the method for manufacturing a resist pattern. These include, for example, the followings: thickening a fine resist pattern; obtaining a fine resist pattern useful as an etching mask; obtaining sufficient resolution even using an exposure machine with an increased numerical aperture; obtaining a fine pattern having a good shape; obtaining a resist pattern with a high aspect ratio; widening the process window; and improving the manufacturing yield.

The present inventors have considered and examined as follows.

DOF (Depth of Focus) refers to the range of depth of focus in which a resist pattern can be formed with dimensions that the difference with respect to the target dimension becomes within a predetermined range when exposure is performed with the focus shifted up and down at the same exposure amount.

DOF is indicated by the following formula:

k2×λ/NA²

wherein, k2 is a constant, λ is the exposure wavelength, and NA is the numerical aperture.

The larger the DOF is, the wider the process window becomes, which is preferable. However, in the high-definition lithography technology such as IC, the NA of exposure machine tends to increase in the future, and it is expected that the DOF will become narrower and narrower.

In the EUV exposure, which is expected as a high-definition technology, it is being achieved to form a fine pattern composed of a thin film. The present inventors have considered that thickening the resist pattern is preferable to make the resist pattern more resistant when the high-definition pattern is used as a mask in a subsequent process. If the resist pattern is thin, for example, when it is used as an etching mask, the durability as a mask cannot be sufficiently achieved, and even the object to be masked may be scraped at the end of the etching process.

If the resist film thickness is thick, the process window tends to become narrow. For example, there is a possibility that if the focus is shifted due to a slight shift of the substrate thickness, the shape of the resist pattern formed may change to become far from the rectangle and that the pattern collapses are likely to occur. In another example, there is a possibility that if the exposure amount (Dose) is shifted, the line width is shifted and that pattern bridges and pattern collapses are likely to occur. In high-definition technology for which high resolution is required, a thinner resist film is easily used.

The present invention has been made based on the above-mentioned technical background and provides a method for manufacturing a thickened resist pattern and a thickening solution used for the method.

### Means for Solving the Problems

The method for manufacturing a thickened resist pattern according to the present invention comprises the following steps:
(1) applying a resist composition above a substrate to form a resist layer from the resist composition;
(2a) exposing the resist layer;
(2b) applying a thickening solution comprising a polymer (A) and a solvent (B) on the resist layer to form a thickening layer; and
(3) developing the resist layer and the thickening layer.

The thickening solution according to the present invention comprises a polymer (A) and a solvent (B) and is used to thicken a resist layer to be applied before the development of the resist layer.

The method for manufacturing a processed substrate according to the present invention comprises the following steps:
forming a thickened resist pattern as mentioned above; and
(4) processing using the thickened resist pattern as a mask.

### Effects of the Invention

According to the present invention, one or more of the following effects can be desired:

Thickening a fine resist pattern; obtaining a fine resist pattern useful as an etching mask; obtaining sufficient resolution even using an exposure machine with an increased numerical aperture; obtaining a fine pattern having a good shape; obtaining a resist pattern with a high aspect ratio; widening the process window; and improving the manufacturing yield.

### BRIEF DESCRIPTION OF THE DRAWINGS

FIG. 1 is a schematic illustration showing one embodiment of the method for manufacturing a thickened resist pattern.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

Hereinafter, embodiments of the present invention are described in detail.

<Method for Manufacturing a Thickened Resist Pattern>

The method for manufacturing a thickened resist pattern according to the present invention comprises the following steps:
(1) applying a resist composition above a substrate to form a resist layer from the resist composition;
(2a) exposing the resist layer;
(2b) applying a thickening solution comprising a polymer (A) and a solvent (B) on the resist layer to form a thickening layer; and
(3) developing the resist layer and the thickening layer.

Hereinafter, each step is described with reference to the FIGURE. Although describing for clarity, the steps (1) and (2) are performed before the step (3). The numbers in parentheses indicating a step mean the order. However, the order of (2a) and (2b) is in any order. The same applies hereinafter.

### Step (1)

In the step (1), a resist composition is applied above the substrate to form a resist layer.

Examples of the substrate include a silicon/silicon dioxide coated substrate, a silicon nitride substrate, a silicon wafer substrate, a glass substrate, and an ITO substrate.

The resist composition is not particularly limited, but from the viewpoint of forming a fine resist pattern with high resolution, it is preferably a chemically amplified resist composition, and for example, a chemically amplified PHS-acrylate hybrid-based EUV resist composition is included. It is also a preferred embodiment that the resist composition comprises a photoacid generator. A suitable resist composition of the present invention is a positive-type chemically amplified resist composition.

A general high-resolution positive-type resist composition comprises a combination of an alkali-soluble resin in which its side chain is protected by a protective group, and a photoacid generator. When the resist layer formed from such a composition is irradiated with ultraviolet ray, electron beam, extreme ultraviolet ray, etc., the photoacid generator releases an acid at the irradiated portion (exposed area), and the protective group binds the alkali-soluble resin is dissociated by the acid (hereinafter referred to as deprotection). Since the deprotected alkali-soluble resin is soluble in an alkaline developer, it is removed by developing processing. In the case of the present application where a thickening layer is formed on the resist layer, if the area of the underlying resist layer is soluble, both the mixed layer and the resist layer in that area are removed. This is described later.

As the resist composition of the present invention, it is also possible to use a negative-type resist composition. Known negative resist compositions and processes can be used. For example, by insolubilizing a polymer with a cross-linking agent or using an organic solvent in the developer, both the resist layer and the mixed layer in the unexposed area are removed.

The resist composition is applied above a substrate by an appropriate method. In the present invention, “above the substrate” includes a case where it is applied immediately above the substrate and a case where it is applied via another layer. For example, a resist underlayer film (for example, SOC (Spin On Carbon) and/or adhesion enhancing film) can be formed immediately on a substrate, and the resist composition can be applied immediately on the resist underlayer film. Preferably, the resist composition is applied immediately on the substrate. Further, in another preferred embodiment, the SOC is formed immediately on the substrate, the adhesion enhancing film is formed immediately on the SOC, and the resist composition is applied immediately on the adhesion enhancing film.

The application method is not particularly limited, but examples thereof include application by spin coating.

Preferably by heating, a resist layer is formed on the substrate on which the resist composition is applied. This heating is also called prebaking and is performed, for example, using a hot plate. The heating temperature is preferably 100 to 250° C.; more preferably 100 to 200° C.; further preferably 100 to 160° C. The temperature here is a heating surface temperature of the hot plate. The heating time is preferably 30 to 300 seconds; more preferably 30 to 120 seconds; further preferably 45 to 90 seconds. The heating is preferably performed in an air or nitrogen gas atmosphere; more preferably in an air atmosphere.

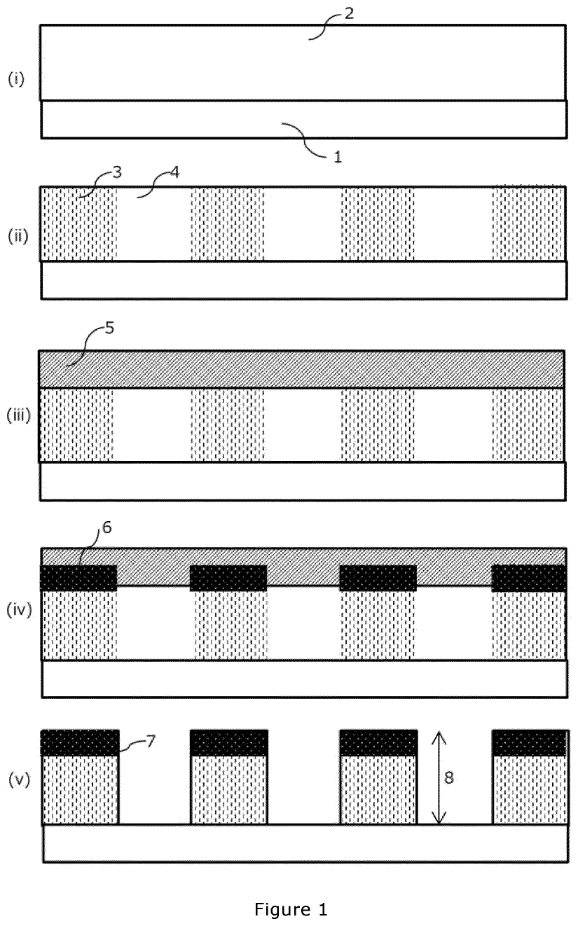

FIG. 1 (i) is a schematic illustration in which a resist layer 2 is formed on a substrate 1. The film thickness of the resist layer is selected depending on the intended purpose, but is preferably 10 to 100 nm; more preferably 10 to 40 nm; and further preferably 10 to 30 nm.

### Step (2a)

In the step (2a), the resist layer is exposed through a mask, if desired.

The wavelength of the radiation (light) used for exposure is not particularly limited, but it is preferable to expose with light having a wavelength of 13.5 to 248 nm. In particular, KrF excimer laser (wavelength: 248 nm), ArF excimer laser (wavelength: 193 nm), EUV (extreme ultraviolet light, wavelength 13.5 nm), or the like can be used. EUV light is more preferred. These wavelengths are accepted in the range of ±1%.

After exposure, post exposure baking (PEB) can be performed, if necessary. The temperature for the PEB can be selected from the range of 70 to 150° C.; preferably 80 to 120° C. The heating time for the PEB can be selected from the range of 0.3 to 5 minutes; preferably 0.5 to 2 minutes.

FIG. 1 (ii) is a schematic illustration showing a state in which the resist layer 2 is exposed through a mask in the case using a typical positive-type chemically amplified resist composition. An acid is released from the photoacid generator to the exposed area 4, whereby the polymer is deprotected and its alkali solubility is increased. In the unexposed area 3, the alkali solubility of the polymer does not change.

### Step (2b)

In the step (2b), a thickening solution comprising the polymer (A) and the solvent (B) is applied on the resist layer to form a thickening layer. In the present invention, the thickening solution is not applied between the resist patterns (after the resist layer is developed).

The application method is not particularly limited, but examples thereof include application by spin coating.

Preferably by heating or spin-drying (more preferably by heating), a thickening layer is formed on the substrate on which the thickening solution is applied. The heating is performed, for example using a hot plate. The heating temperature is preferably 45 to 150° C.; more preferably 90 to 130° C. The heating time is preferably 30 to 180 seconds; more preferably 45 to 90 seconds. The heating is preferably performed in an air or nitrogen gas atmosphere, more preferably in an air atmosphere. The heating in the step (2b) is also referred to as mixing bake.

The order of (2a) and (2b) can be in any order. Since it is not necessary to expose while passing through the thickening layer, the process of performing the step (2b) after (2a) is more preferable. A process in which the step (2a) is performed after (2b) is also possible, and in this case, it is preferable to perform the exposure after controlling the influence of its transmission through the thickening layer.

FIG. 1 (iii) is a schematic illustration of a state in which the thickening layer 5 is formed on the resist layer 2.

In the step (2b), an insolubilized layer is preferably formed in a region in the vicinity where the thickening layer and the resist layer are in contact with each other. Without wishing to be bound by theory, it is considered that each polymer permeates (intermixing) in the region where the thickening layer and the resist layer are in contact with each other to form a mixed layer. Whether the mixed layer is soluble or insoluble in the developer in the subsequent developing process depends on whether the underlying resist layer is soluble or insoluble in the developer. If the region of the underlying resist layer is insoluble in the developer, the mixed layer becomes an insolubilized layer. If the region of the underlying resist layer is soluble in the developer, the mixed layer also becomes soluble.

An instance of a positive-type resist layer is explained. Since the exposed area of the resist layer is soluble in the developer, the resist layer (matrix component, preferably a polymer) that has permeated the mixed layer in the same area is dissolved, and the mixed layer is also dissolved. Further, the exposed area of the resist layer under the mixed layer is also dissolved. On the other hand, the unexposed area of the resist layer is insoluble in the developer (for example, it is not deprotected). Therefore, the resist layer that permeates the mixed layer in the same area is insoluble, and the mixed layer also does not dissolve. Further, the unexposed area of the resist layer under the mixed layer also does not dissolve.

FIG. 1 (iv) is a schematic illustration of a state in which an insolubilized layer 6 is formed. A mixed layer is also formed in the area that dissolves (exposed area, in the case of the positive type), but it is not shown in (iv) for convenience because it is dissolved and removed in the developing process.

In the step (2b), it is also preferable to perform rinsing after forming the thickening layer to remove the upper part of the thickening layer (thickening layer upper than the mixed layer). For the rinsing, one having the same composition as the solvent (B) of the thickening solution can be used, and water (for example, DIW) can be preferably used. The rinsing in the present invention is different from the development described later. That is, the rinsing is not for dissolving the soluble area of the resist layer to form a resist pattern.

### [Thickening Solution]

The thickening solution according to the present invention comprises a polymer (A) and a solvent (B), and is used to thicken the resist layer applied before the development of the resist layer. The thickening solution according to the present invention is not applied between the resist patterns after development. However, the “development” within the expression of “after development” does not include the development when the already removed resist layer has been patterned. For example, in the case of a design in which resist patterning is performed a plurality of times in succession, it is possible to use the thickening solution of the present invention to thicken the resist layer in the subsequent process even after the resist has been developed in the previous process.

### (A) Polymer

The polymer (A) used in the present invention is not particularly limited as long as it has a good affinity with the resist pattern, and examples thereof include polyacrylic acid, vinyl resin, and the like.

Preferably, the polymer (A) is a polymer comprising an amino group in a repeating unit. Here, the amino group refers to a primary amino group (—NH₂), a secondary amino group (—NHR), and a tertiary amino group (—NRR′). Here, the amino group also includes one in which nitrogen binds an adjacent element via a double bond, such as —N═. These amino groups can be contained in the side chain of the repeating unit or can be contained in the main chain structure of the polymer.

The polymer (A) is preferably a polymer comprising at least one selected from the group consisting of a repeating unit (A1) represented by the formula (a1) and a repeating unit (A2) represented by the formula (a2). An embodiment in which the polymer (A) comprises a repeating unit (A1) represented by the formula (a1) is more preferable.

The repeating unit (A1) represented by the formula (a1) is as follows:

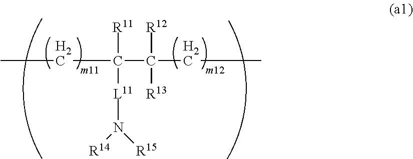

where,
R¹¹, R¹² and R¹³ are each independently H, C₁₋₄ alkyl or carboxy. R₁₁ and R¹² are preferably H. R¹³ is preferably H or methyl; more preferably H.
L¹¹ is a single bond or C₁₋₄ alkylene; preferably a single bond or methylene; more preferably a single bond.
R¹⁴ is a single bond, H or C₁₋₅ alkyl; preferably a single bond, H, methyl, ethyl, n-propyl or n-butyl; more preferably a single bond, H or methyl. When R¹⁴ is a single bond, it binds R¹³.
R¹⁵ is H, C₁₋₅ alkyl, C₁₋₅ acyl or formyl (—CHO); preferably H, methyl, ethyl, n-propyl, n-butyl, acetyl or formyl; more preferably H, methyl, ethyl or n-propyl; further preferably H or n-propyl.

At least one of —CH₂— in the alkyl of L¹¹, the alkyl of R¹⁴ and the alkyl or acyl of R¹⁵ can be each independently replaced with —NH—. Preferably, one of —CH₂— in the alkyl or acyl of R¹⁵ is replaced with —NH—. An embodiment in which the replacement of —NH— does not occur is also preferable.

The single bond or alkyl of R¹⁴ and the alkyl of R¹³ can be combined together to form a saturated or unsaturated heterocycle. Preferably, the single bond of R¹⁴ and the alkyl of R¹³ can be combined together to form a saturated heterocycle. An embodiment in which the heterocycle is not formed is also preferable.

The alkyl of R¹⁴ and the alkyl, acyl or formyl of R¹⁵ can be combined together to form a saturated or unsaturated heterocycle. Preferably, the alkyl of R¹⁴ and the alkyl of R¹⁵ are combined together to form an unsaturated heterocycle. —CH₂— in R¹⁴ and/or R¹⁵ used for the binding can be replaced with —NH—. An embodiment in which the heterocycle is not formed is also preferable.

m11 and m12 are each independently a number of 0 to 1; preferably 0 or 1; more preferably 0.

The repeating unit of polyvinylimidazole (P1) described later is explained with reference to the formula (a1). m11=m12=0. R¹¹, R¹² and R¹³ are H. LIA is a single bond. R¹⁴ is methyl. R¹⁵ is C₃ alkyl (n-propyl) and one of —CH₂— is replaced with —NH—. Further, the alkyl of R¹⁴ and the alkyl of R¹⁵ are bonded to form an unsaturated heterocycle (imidazole).

The repeating unit of polyallylamine (P2) described later is explained with reference to the formula (a1). m11=m12=0. R¹¹, R¹² and R¹³ are H. L¹¹ is methylene. R¹⁴ and R¹⁵ are H.

The repeating unit of vinylpyrrolidone-vinylimidazole copolymer (P3) described later is explained with reference to the formula (a1). The polymer having (A1) has two kinds of repeating units, each of which is represented by the formula (a1). The relevant parts of vinyl imidazole is the same as those of P1 described above. The relevant parts of vinylpyrrolidone are explained. m11=m12=0. R¹¹, R¹² and R¹³ are H. L¹¹ is a single bond. R¹⁴ is C₂ alkyl (ethyl). R¹⁵ is C₂ acyl (CH₃—CO—, acetyl). The alkyl of R¹⁴ and the acyl of R¹⁵ are combined together to form a saturated heterocycle (2-pyrrolidone). They are randomly copolymerized with a repeating unit ratio of 4:6 of the vinyl imidazole-corresponding parts and the vinylpyrrolidone-corresponding parts.

The repeating unit of the following polydiallylamine is explained with reference to the formula (a1). m11=m12=1. R¹¹ and R¹² are H. L¹¹ is methylene and R¹³ is methyl. R¹⁴ is a single bond and binds R¹³ to form a saturated heterocycle. R¹⁵ is H.

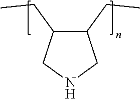

The following repeating unit is explained with reference to the formula (a1). m11=m12=0. R¹¹, R¹² and R¹³ are H. L¹¹ is a single bond. R¹⁴ is C₄ alkyl (n-butyl). R¹⁵ is C₂ acyl (CH₃—CO—, acetyl). The alkyl of R¹⁴ and the acyl of R¹⁵ are combined together to form a saturated heterocycle.

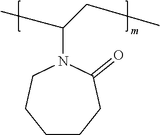

Examples of the polymer having (A1) include polyvinylimidazole, polyvinylamine, polyallylamine, polydiallylamine, and vinylpyrrolidone-vinylimidazole copolymer. The polymer (A) can be a copolymer having two or more kinds of (A1), and examples thereof include vinylpyrrolidone-vinylimidazole copolymer and poly (allylamine-co-diallylamine). The repeating units comprised in the polymer having (A1) are one or two kinds; more preferably one kind. When a copolymer is used, the repeating unit comprised in the polymer having (A1) is preferably two kinds.

The repeating unit (A2) represented by the formula (a2) is as follows:

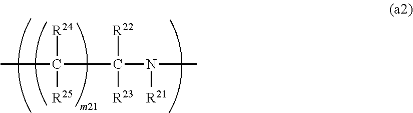

where,
R²¹ is each independently H, a single bond, C₁₋₄ alkyl or carboxy (—COOH); preferably H, a single bond or methyl; more preferably H or a single bond; further preferably H. The single bond of R²¹ is used as a repeating unit to another repeating unit (A2). To the single bond that is not used at the end of the polymer, H or the like can bind.
R²², R²³, R²⁴ and R²⁵ are each independently H, C₁₋₄ alkyl or carboxy; preferably H or methyl; more preferably H.
m21 is a number of 0 to 3; preferably 0 or 1; more preferably 1.

Examples of the polymer having (A2) include polyethyleneimine. Polyethyleneimine can be linear or branched; linear is more preferred.

The linear polyethyleneimine is explained with reference to the formula (a2). m21=1, and R²¹, R²², R²³, R²⁴ and R²⁵ are H.

The branched polyethyleneimine is explained with reference to the formula (a2). m21=1 and R²¹ is H or a single bond. R²², R²³, R²⁴ and R²⁵ are H.

The polymer (A) can be a copolymer having two or more kinds of (A2). Preferably, the repeating units comprised in the polymer having (A2) are one or two kinds; more preferably one kind. The polymer (A) can be a copolymer having (A1) and (A2).

The polymer (A) can be appropriately selected from the above-mentioned ones from the viewpoint of the type of resist composition to be applied, availability of the polymer, or the like, and is preferably selected from the group consisting of polyvinylimidazole, polyvinylamine, polyallylamine, polydiallylamine, polyethyleneimine, vinylpyrrolidone-vinylimidazole copolymer and poly(allylamine-co-dialylamine).

The polymer (A) can be a copolymer comprising a repeating unit comprising no amino group as long as the scope of the present invention is not impaired. For example, the copolymer comprising polyacrylic acid, polymethacrylic acid, polyvinyl alcohol and the like as a copolymerization unit can be mentioned.

Considering the affinity with the polymer in the resist, the repeating unit containing no amino group is preferably 50 mol % or less; more preferably 30 mol % or less; further preferably 5 mol % or less, based on the total repeating unit constituting the polymer (A). It is also a preferred embodiment of the present invention that the repeating unit containing no amino group is 0 mol % (not contained).

The mass average molecular weight of the polymer (A) is preferably 5,000 to 200,000; more preferably 5,000 to 150,000; further preferably 6,000 to 10,000. In the present invention, the mass average molecular weight (Mw) means a mass average mass molecular weight in terms of polystyrene, which is measured by the gel permeation chromatography.

The content of the polymer (A) is preferably 1 to 30 mass %; more preferably 1 to 20 mass %; further preferably 2 to 10 mass %, based on the total mass of the thickening solution.

The thickening solution comprises the polymer (A), but can comprise any polymer other than the polymer (A) (preferably a polymer having a repeating unit that contains no amino group). The content of the polymer other than the polymer (A) is preferably 0 to 20 mass %; more preferably 0 to 10 mass %; further preferably 0 to 5%; and further more preferably 0 mass % (embodiment in which it is not contained), based on the total mass of the thickening solution.

### (B) Solvent

The solvent (B) is for dissolving the polymer (A) and other components used as needed. Such a solvent is required not to dissolve the resist layer. The solvent (B) preferably comprises water. The water is preferably deionized water (DIW). Since it is used for forming a fine resist pattern, it is preferable that the solvent (B) has few impurities. The preferred solvent (B) has impurities of 1 ppm or less; more preferably 100 ppb or less; and further preferably 10 ppb or less. It is also a preferred embodiment of the present invention to prepare a thickening solution by filtering a solution in which solutes are dissolved for use in a fine process.

The content of water is preferably 80 to 100 mass %; more preferably 90 to 100 mass %; further preferably 98 to 100 mass %; and further more preferably 100 mass %, based on the total mass of the solvent (B). In a preferred embodiment of the present invention, the solvent (B) substantially consists only of water. However, an embodiment in which an additive is contained in the thickening solution according to the present invention in a state being dissolved and/or dispersed in a solvent other than water (for example, a surfactant) is acceptable as a preferred embodiment of the present invention.

Exemplified embodiments of the solvent (B) excluding water suitably include cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol 1-monomethyl ether 2-acetate (PGMEA), propylene glycol monoethyl ether acetate, propylene glycol monopropyl ether acetate, γ-butyrolactone, ethyl lactate, or a mixture of any of these. These are preferable in terms of storage stability of the solution. Two or more kinds of these solvents can be mixed and used.

The content of the solvent (B) is preferably 70 to 99 mass %; more preferably 80 to 99 mass %; and further preferably 90 to 98 mass %, based on the total mass of the thickening solution.

The pH of the entire thickening solution is preferably 5 to 12; more preferably 7 to 12; and further preferably 9 to 12.

### (C) Acid

The thickening solution according to the present invention can further comprise an acid (C). Although not to be bound by theory, it is considered that incorporation of the acid (C) makes it possible to regulate the pH of the thickening solution, which tends to be basic due to the polymer (A). It is considered that the dissolution of the polymer in the partially deprotected resist layer existing on the surface of the resist layer can be suppressed.

The acid (C) includes sulfonic acid, carboxylic acid, sulfuric acid, nitric acid, or at least a mixture of any two of these; preferably sulfonic acid, sulfuric acid or nitric acid; more preferably sulfonic acid or nitric acid. Examples of the sulfonic acid include p-toluenesulfonic acid, benzenesulfonic acid, p-dodecylbenzenesulfonic acid, 1,4-naphthalenedisulfonic acid and methanesulfonic acid; preferably p-toluenesulfonic acid. Examples of the carboxylic acid include acetic acid, formic acid, oxalic acid, maleic acid, fumaric acid, o-phthalic acid and succinic acid.

The pH of the entire thickening solution can be controlled by the amount of the acid (C) added. It is preferable not to use, as the acid (C), an acid that is strong in the extent to modify the resist film. For example, it is preferable that the resist film is not deprotected by the acid (C).

The content of the acid (C) is preferably 0 to 20 mass %; more preferably 0 to 15 mass %; further preferably 0.1 to 10 mass %; and further more preferably 0.1 to 5 mass %, based on the total mass of the thickening solution. It is also a preferred embodiment of the present invention that the thickening solution contains no acid (C) (0 mass %).

### (D) Surfactant

The thickening solution according to the present invention can further comprise a surfactant (D). The coatability can be improved by including the surfactant (D). Examples of the surfactant that can be used in the present invention include (I) anionic surfactants, (II) cationic surfactants, or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Megafac (DIC), Surflon (AGC) and organic siloxane surfactants (for example, KF-53, KP341 (Shinetsu Chemical Industry)).

These surfactants can be used alone or in combination of two or more of these.

The content of the surfactant (D) is preferably 0 to 5 mass %; more preferably 0.001 to 2 mass %; further preferably 0.01 to 1 mass %, based on the total mass of the thickening solution. It is also one embodiment of the present invention that the thickening solution contains no surfactant (D) (0 mass %).

### (E) Additive

The thickening solution according to the present invention can further comprise an additive (E) other than the above-mentioned components (A) to (D). The additive (E) is preferably a plasticizer, a cross-linking agent, an antibacterial agent, a germicide, an antiseptic, an antifungal agent, a base or a mixture of any of these. Preferably, the additive (E) comprises a base; more preferably consists of a base. The base is a low molecular weight compound unlike the polymer (A) containing an amino group. The molecular weight of the low molecular weight compound is 50 to 200; preferably 70 to 150; more preferably 100 to 125.

Examples of such a base include tertiary amines, diamines, and amine compounds having a cage-type three-dimensional structure.

As the diamine compounds, followings are included: N,N,N′,N′-tetramethylethylene diamine, N,N,N′,N′-tetraethylethylene diamine, N,N,N′,N′-tetrapropylethylene diamine, N,N,N′,N′-tetraisopropylethylene diamine, N,N,N′,N′-tetramethyl-1,2-propylene diamine, N,N,N′,N′-tetraethyl-1,2-propylene diamine, N,N,N′,N′-tetrapropyl-1,2-propylene diamine, N,N,N′,N′-tetraisopropyl-1,2-propylene diamine, N,N,N′,N′-tetramethyl-1,3-propylene diamine, N,N,N′,N′-tetraethyl-1,3-propylene diamine, N,N,N′,N′-tetrapropyl-1,3-propylene diamine, N,N,N′,N′-tetraisopropyl-1,3-propylene diamine, N,N,N′,N′-tetramethyl-1,2-butylene diamine, N,N,N′,N′-tetraethyl-1,2-butylene diamine, N,N,N′,N′-tetrapropyl-1,2-butylene diamine, N,N,N′,N′-tetraisopropyl-1,2-butylene diamine, N,N,N′,N′-tetramethyl-1,3-butylene diamine, N,N,N′,N′-tetraethyl-1,3-butylene diamine, N,N,N′,N′-tetrapropyl-1,3-butylene diamine, N,N,N′,N′-tetraisopropyl-1,3-butylene diamine, N,N,N′,N′-tetramethyl-1,4-butylene diamine, N,N,N′,N′-tetraethyl-1,4-butylene diamine, N,N,N′,N′-tetrapropyl-1,4-butylene diamine, and N,N,N′,N′-tetraisopropyl-1, 4-butylene diamine.

As the amine compounds having a cage-type three-dimensional structure, followings are included: 1,4-diazabicyclo[2.2.2]octane, 2-methyl-1,4-diazabicyclo [2.2.2]octane, 1,4-diazabicyclo[2.2.2]octane-2-one, 1,4-diaza-2-oxabicyclo[2.2.2]octane, 1,5-diazabicyclo-[3.2.2]nonane, 1,5-diazabicyclo[3.3.2]decane, and 1,5-diazabicyclo[3.3.3]undecane. It is a preferred embodiment of the present invention that the base of the additive (E) is 1,4-diazabicyclo[2.2.2]octane. Although not to be bound by theory, it is considered that penetration of the thickening solution into the resist layer can be promoted by including the base of the additive (E), and that the underlying resist layer further expands.

The content of the additive (E) is preferably 0 to 10 mass %; more preferably 0.001 to 5 mass %; further preferably 0.01 to 4 mass %; and further more preferably 0.1 to 3 mass %, based on the total mass of the thickening solution. It is also a preferred embodiment of the present invention that the thickening solution according to the present invention contains no additive (E) (0 mass %).

### Step (3)

In the step (3), the resist layer and the thickening layer are developed.

Examples of the application method of the developer include a paddle method, a dip method and a spray method. The temperature of the developer is preferably 5 to 50° C.; more preferably 25 to 40° C., and the developing time is preferably 15 to 120 seconds; more preferably 30 to 60 seconds. After applying the developer, the developer is removed. The resist pattern after development can be also subjected to rinsing treatment. The rinsing treatment can preferably be carried out with water (DIW).

The developer is preferably an alkaline aqueous solution or an organic solvent; more preferably an alkaline aqueous solution. Examples of the alkaline aqueous solution include inorganic alkalis such as sodium hydroxide, potassium hydroxide, sodium carbonate and sodium silicate, organic amines such as ammonia, ethylamine, propylamine, diethylamine, diethylaminoethanol and triethylamine, and an aqueous solution containing a quaternary amine such as tetramethylammonium hydroxide (TMAH) or the like; more preferably a TMAH aqueous solution; further preferably a 2.38 mass % TMAH aqueous solution.

The above-mentioned surfactant can be further added to the developer.

FIG. 1 (v) shows a state in which the developer is applied to the resist layer and the thickening layer, the developer is removed, and the thickened resist pattern 7 is formed

When (height of the thickened resist pattern)−(height of the resist pattern formed in the same manner except that the thickening solution is not applied) is taken as the thickened amount, the thickened amount is preferably 2 to 20 nm; more preferably 2 to 15 nm; further preferably 3 to 10 nm; further more preferably 3 to 8 nm. Although not to be bound by theory, in high-definition lithography techniques such as EUV exposure, it is general that thickness of the resist film is thin. However, it is considered that by thickening the resist film according to the present invention, when used in a later step, for example, as an etching mask, the durability as a mask can be ensured.

### <Method for Manufacturing a Processed Substrate and Device>

The method for manufacturing a processed substrate according to the present invention comprises the following steps:
forming a thickened resist pattern as described above; and
(4) processing using the thickened resist pattern as a mask.

### Step (4)

In the step (4), processing is performed using the thickened resist pattern as a mask.

The thickened resist pattern is preferably used for processing a resist underlayer film or a substrate (more preferably a substrate). In particular, using the resist pattern as a mask, various substrates that becomes an underlaying material can be processed by means of a dry etching method, a wet etching method, an ion implantation method, a metal plating method, or the like. Since the resist pattern is thickened, it can function as a mask even under severe conditions, and therefore, it is preferably used for processing by a dry etching method.

When processing the resist underlayer film using the thickened resist pattern, the processing can be performed step by step. For example, the resist pattern can be used to process the adhesion enhancing film and the SOC, and the SOC pattern can be used to process the substrate. As the adhesion enhancing film, for example, SiARC (Si anti-reflective coating) can be used.

The method for manufacturing a device according to the present invention comprises the above method, and preferably further comprises a step of forming a wiring on the processed substrate. Known methods can be applied to these processings. Thereafter, if necessary, the substrate is cut into chips, connected to a lead frame, and packaged with resin. In the present invention, this packaged one is referred to as a device. Examples of the device include a semiconductor device, a liquid crystal display device, an organic EL display device, a plasma display device, and a solar cell device. The device is preferably a semiconductor device.

### EXAMPLES

The present invention is described below with reference to various examples. In addition, the embodiments of the present invention are not limited to these examples.

### [Preparation of Thickening Solutions 1 to 3]

The polymer (A), surfactant (D), and base (E) described in Table 1 are dissolved in the solvent (B). The respective contained amounts are as shown in Table 1. The numerical values in Table 1 are the contents of each component (mass %) based on the total mass of the thickening solution.

The obtained solution is stirred at room temperature for 60 minutes. After visually confirming that the solutes are completely dissolved, this solution is filtered through a 0.2 μm fluoride resin filter to obtain the thickening solutions 1 to 3.

TABLE 1

| | Polymer | | Solvent | | Surfactant | | Base | |
|---|---|---|---|---|---|---|---|---|
| | (A) | | (B) | | (D) | | (E) | |
| Thickening solution 1 | P1 | 5.0% | DIW | 93.45% | S1 | 0.05% | 1,4-diazabicyclo[2.2.2]octane | 1.5% |
| Thickening solution 2 | P2 | 5.0% | DIW | 92.95% | S1 | 0.05% | 1,4-diazabicyclo[2.2.2]octane | 2.0% |
| Thickening solution 3 | P3 | 5.0% | DIW | 92.95% | S1 | 0.05% | 1,4-diazabicyclo[2.2.2]octane | 2.0% |

In the table,
P1: polyvinylimidazole (Mw: 30,000),

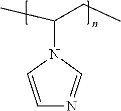

P2: polyallylamine (Mw 8,000),

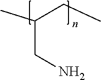

P3: random copolymer of vinylpyrrolidone and vinylimidazole (m:n=4:6, Mw: 25,000),

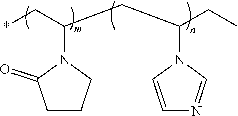

S1: acetylene-based diol polyoxyalkylene ether having the following structure:

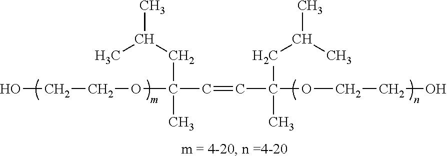

### Example 1

A silicon substrate is subjected to HMDS (hexamethyldisilazane) treatment at 90° C. for 30 seconds. A chemically amplified PHS-acrylate hybrid-based resist composition (positive type) is applied on the HMDS-treated substrate by spin coating and the substrate is heated on a hot plate at 110° C. for 60 seconds to form a resist layer having a film thickness of 35 nm. The resist layer is exposed using an EUV exposure apparatus (NXE: 3300B, ASML) through a mask having a size of 18 nm (line:space=1:1) while changing the exposure amount. Thereafter, post-exposure baking (PEB) is performed at 100° C. for 60 seconds. Thereafter, the thickening solution 1 is applied onto the resist layer by spin coating to form a thickening layer, and heated at 130° C. for 60 seconds. Thereafter, paddle development is performed for 30 seconds using a 2.38 mass % TMAH aqueous solution as a developer, water starts to be dropped in a state that the developer is paddled on the substrate, and water is continued to be dropped while rotating the substrate, and the developer is replaced with water. Thereafter, the substrate is rotated at high speed and the thickened resist pattern of Example 1 is dried.

For comparison, a resist pattern is formed without performing the application of the thickening solution. In particular, a resist pattern is formed in the same manner as in Example 1 except that the application of the thickening solution and the subsequent heating are not performed. This is referred to as the comparative resist pattern.

### [Evaluation]

Chips of the substrates respectively of the thickened resist pattern of Example 1 and the comparative resist pattern are formed, and the cross-sectional shapes thereof are observed with SEM (SU8230, Hitachi High-Tech Fielding), and the heights of the patterns are measured. (Height of the thickened resist pattern)−(height of the comparative resist pattern) is calculated as the thickened amount. The results obtained are shown in Table 2.

In Examples 2 and 3, the thickened amounts are calculated in the same manner as in Example 1 except that the kind of the thickening solution is changed to that shown in Table 2. The results obtained are shown in Table 2.

TABLE 2

| | | Thickended amount (nm) |
|---|---|---|
| Example 1 | Thickening solution 1 | 5 |
| Example 2 | Thickening solution 2 | 4 |
| Example 3 | Thickening solution 3 | 4 |

### EXPLANATION OF SYMBOLS

1. substrate
2. resist layer
3. unexposed area
4. exposed area
5. thickening layer
6. insolubilized layer
7. thickened resist pattern
8. height of thickened resist pattern

1.-15. (canceled)

16. A method for manufacturing a thickened resist pattern comprising the following steps:
(1) applying a resist composition above a substrate to form a resist layer from the resist composition;
(2a) exposing the resist layer;
(2b) applying a thickening solution comprising a polymer (A) and a solvent (B) on the resist layer to form a thickening layer; and
(3) developing the resist layer and the thickening layer.

17. The method according to claim 16, which comprises
(1) applying by heating the resist composition above the substrate to form the resist layer from the resist composition;
(2a) exposing the resist layer with EUV light;
(2b) applying a thickening solution comprising a polymer (A) and a solvent (B) on the resist layer to form a thickening layer by heating or spin-drying; and
(3) developing the resist layer and the thickening layer with an alkaline aqueous solution or an organic solvent.

18. The method according to claim 16, further comprising removing the upper part of the thickening layer by rinsing after forming the thickening layer in the step (2b).

19. The method according to claim 16, wherein in the step (2b), an insolubilized layer is formed in a region in the vicinity where the thickening layer and the resist layer are in contact with each other.

20. The method according to claim 16, wherein the polymer (A) is a polymer comprising an amino group in a repeating unit.

21. The method according to claim 16, wherein the polymer (A) is a polymer comprising at least one selected from the group consisting of a repeating unit (A1) represented by the formula (a1) and a repeating unit (A2) represented by the formula (a2): 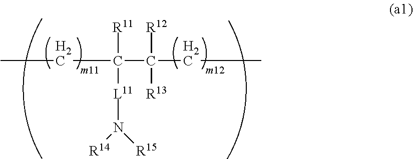
where,
R¹¹, R¹² and R¹³ are each independently H, C₁₋₄ alkyl or carboxy (preferably H),
L¹¹ is a single bond or C₁₋₄ alkylene,
R¹⁴ is a single bond, H or C₁₋₅ alkyl,
R¹⁵ is H, C₁₋₅ alkyl, C₁₋₅ acyl or formyl,
where, at least one of —CH₂— in the alkyl of L¹¹, the alkyl of R¹⁴ and the alkyl or acyl of R¹⁵ can be each independently replaced with —NH—, the single bond or alkyl of R¹⁴ and the alkyl of R¹³ can be combined together to form a saturated or unsaturated heterocycle, and the alkyl of R¹⁴ and the alkyl, acyl or formyl of R¹⁵ can be combined together to form a saturated or unsaturated heterocycle, and
m11 and m12 are each independently a number of 0 to 1. 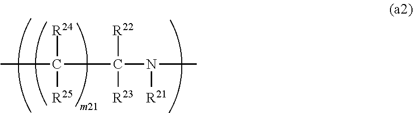
where,
R²¹ is each independently H, a single bond, C₁₋₄ alkyl or carboxy (preferably H),
R²², R²³, R²⁴ and R²⁵ are each independently H, C₁₋₄ alkyl or carboxy (preferably H), and
m21 is a number of 0 to 3.

22. The method according to claim 21, wherein
R¹¹, R¹² and R¹³ are each H,
R²¹ is H, and
R²², R²³, R²⁴ and R²⁵ are each H.

23. The method according to claim 16, wherein the polymer (A) is selected from the group consisting of polyvinylimidazole, polyvinylamine, polyallylamine, polydiallylamine, polyethyleneimine, vinylpyrrolidone-vinylimidazole copolymer and poly(allylamine-co-diallylamine).

24. The method according to claim 16, wherein the solvent (B) comprises water:
the content of the polymer (A) is 1 to 30 mass % based on the total mass of the thickening solution; or
the content of the solvent (B) is 70 to 99 mass % based on the total mass of the thickening solution.

25. The method according to claim 16, wherein the solvent (B) comprises water:
and the content of water is 80 to 100 mass % based on the total mass of the solvent (B);
the content of the polymer (A) is 1 to 20 mass % based on the total mass of the thickening solution; or
the content of the solvent (B) is 80 to 99 mass % based on the total mass of the thickening solution.

26. The method according to claim 16, wherein the thickening solution further comprises an acid (C) wherein the content of the acid (C) is 0 to 20 mass % based on the total mass of the thickening solution and
the pH of the entire thickening solution is 5 to 12.

27. The method according to claim 26, wherein the
content of the acid (C) is 0.1 to 10 mass % based on the total mass of the thickening solution;
and the pH of the entire thickening solution is 5 to 10 or
the acid (C) is a sulfonic acid, a carboxylic acid, a sulfuric acid, a nitric acid or a mixture of any of these.

28. The method according to claim 16, wherein the thickening solution further comprises a surfactant (D):
and the content of the surfactant (D) is 0 to 5 mass % based on the total mass of the thickening solution;
the thickening solution further comprises an additive (E);
the additive (E) is a plasticizer, a cross-linking agent, an antibacterial agent, a germicide, an antiseptic, an antifungal agent, a base or a mixture of any of these; or
the content of the additive (E) is 0 to 10 mass % based on the total mass of the thickening solution.

29. The method according to claim 28, wherein the thickening solution further comprises a surfactant (D):
and the content of the surfactant (D) is 0.001 to 2 mass % based on the total mass of the thickening solution;
or
the content of the additive (E) is 0.001 to 5 mass % based on the total mass of the thickening solution.

30. The method according to claim 16, wherein the resist composition is a chemically amplified resist composition.

31. The method according to claim 31, wherein the resist composition further comprises a photoacid generator.

32. A thickening solution to be applied before the development of a resist layer for thickening the resist layer, comprising a polymer (A) and a solvent (B).

33. The thickening solution according to claim 32, wherein the thickening solution is not one to be applied between resist patterns.

34. A method for manufacturing a processed substrate comprising the following steps:
forming a thickened resist pattern according to claim 16; and
(4) processing using the thickened resist pattern as a mask.

35. A method for manufacturing a device comprising the method according to claim 34:
further comprising a step of forming a wiring on the processed substrate.
